(19) United States
(12) Patent Application Publication
(10) Pub. No.: US 2019/0121402 A1
(43) Pub. Date: Apr. 25, 2019

(54) COMPUTER CHASSIS WITH PARALLEL BACKPLANES

(71) Applicant: Intel Corporation, Santa Clara, CA (US)

(72) Inventors: Sudeep Puligundla, Hillsboro, OR (US); Gene F. Young, Lexington, SC (US)

(21) Appl. No.: 15/792,431

(22) Filed: Oct. 24, 2017

(51) Int. Cl. G06F 1/18; H05K 7/14; G06F 1/20

(52) U.S. Cl. CPC G06F 1/183; G06F 1/20; H05K 7/1422; H05K 7/1488

(57) ABSTRACT

Computer chassis with parallel backplanes are disclosed that include a first backplane with a first surface that can receive a first computing node. The computer chassis may further include a second backplane with a second surface that can receive a second computing node, and may include a chassis that encloses the first backplane, second backplane, first computing node, and second computing node. The first backplane and second backplane may be substantially parallel to each other, with the first surface facing the second surface. Other may be described and/or claimed.

### TECHNICAL FIELD

Embodiments described herein generally relate to computer hardware; specifically, the layout of the internal components of a computer.

### BACKGROUND

Computer systems have internal components that may be laid out in a variety of configurations. Typical components common to computer systems can include one or more processors and supporting circuitry, peripheral interconnects such as Peripheral Component Interconnect Express (PCIe) slots, power supplies, and cooling fans. These components may exist in multiples. Some systems, especially systems intended to be used a servers, may have multiple processors and power supplies configured in a redundant fashion. Some systems favor a modular approach, where processors are installed onto cards that in turn can quickly plug into a backplane, allowing for easy upgrades or repairs. In some configurations, the backplane or backplanes may include peripheral interconnects to further ease upgrading or replacing a processor card.

One concern in system design is the electrical distance between components, such as a processor and a peripheral interconnect. Interconnect specifications may mandate a particular maximum electrical length between components, electrical length being the physical distance an electrical signal may travel over a wire or copper trace between its origination point and its destination. Greater electrical lengths may result in increasing losses in the electrical signal due to various factors, such as resistance of the conductor. Where electrical lengths exceed interconnect specifications, deployment and use of retimers, high-grade connectors and/or circuit boards, or other suitable devices may be necessary to ensure the integrity of the electrical signals. These devices may increase the cost of building a system and/or add complexity and points of failure.

### BRIEF DESCRIPTION OF THE DRAWINGS

FIG. 1A is an example perspective view of a layout of computer components according to various embodiments.

FIG. 1B is an example side view of the computer components according to various embodiments.

FIG. 2A is an example cross-sectional view of the computer components according to various embodiments.

FIG. 2B is another example cross-sectional view of the computer components according to various embodiments.

FIG. 3A is an example rear cut-away view of the computer components according to various embodiments.

FIG. 3B is an example rear view of the computer chassis according to various embodiments.

FIG. 4 is an example flowchart of a method according to embodiments.

FIG. 5 illustrates an example computing device suitable for use with various components of an optoelectronic system, such as a transmitter having the multiplexer with the echelle grating with the reduced back-reflection and/or receiver having the demultiplexer with the echelle grating with the reduced back-reflection, in accordance with various embodiments.

### DESCRIPTION OF EMBODIMENTS

Embodiments of the present disclosure are directed toward computer chassis with parallel backplanes that may include a first backplane with a first surface that can receive a first computing node. The computer chassis may further include a second backplane with a second surface that can receive a second computing node, and may include a chassis that encloses the first backplane, second backplane, first computing node, and second computing node. The first backplane and second backplane may be substantially parallel to each other, with the first surface facing the second surface, to create a space between the first backplane and second backplane. The first and second backplane may each include one or more peripheral connectors, and each computing node may be directly connected to a peripheral connector. One or more cooling fans may be disposed within the space to provide cooling airflow to the backplanes, computing nodes, and any peripherals connected to a peripheral connector. Other advantages may be realized, as discussed below in greater detail.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

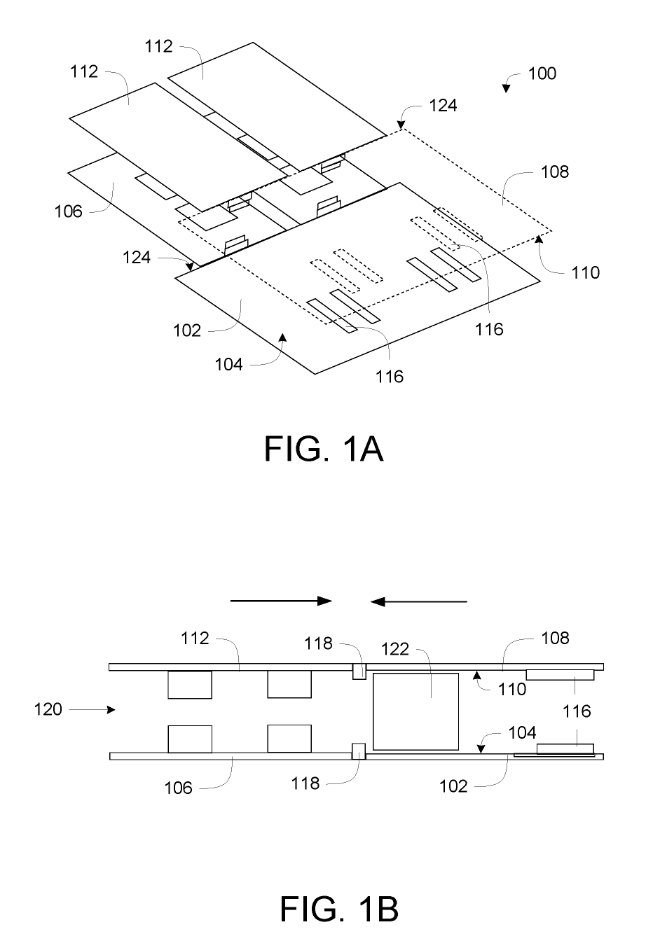

Referring to FIGS. 1A and 1B, computer 100 includes a first backplane 102 with a first surface 104 that can receive a first computing node 106, a second backplane 108 with a second surface 110 that can receive a second computing node 112, and a chassis 114 that encloses the first backplane 102, second backplane 108, first computing node 106, and second computing node 112. First backplane 102 and second backplane 108 are substantially parallel to each other, with first surface 104 facing second surface 110.

First backplane 102 and second backplane 108 each may include a printed circuit board (PCB), and may be configured with one or more peripheral connectors 116. Each backplane 102 and 108 may further be equipped with one or more computing node connectors 118, to allow connection and swapping of computing nodes, including first computing node 106 and second computing node 112. For example, in FIGS. 1A and 1B, each backplane 102 and 108 are shown having two connected computing nodes, resulting in two first computing nodes 106 and two second computing nodes 112. Backplanes 102 and 108 may optionally include additional components for supporting a computer system. While the figures depict first backplane 102 having two computing nodes 106, and second backplane 108 having two computing nodes 112, this is not intended to be limiting. First and second backplanes 102 and 106 each may have one or more computing nodes, dependent upon the size of enclosing chassis 114.

Disposing first backplane 102 and second backplane 108 so that first surface 104 faces second surface 110 may create an interior space 120, into which components of first and second computing nodes 106 and 112, as well as peripheral connectors 116 and any component(s) inserted into peripheral connector(s) 116, extend. One or more fans 122 may be inserted into interior space 120 between first backplane 102 and second backplane 108. These fans 122 may be oriented so as to move air across the various components of first and second computing nodes 106 and 112, first and second backplanes 102 and 108, and any other associated components and/or peripherals that may be positioned within interior space 120. It can be seen from the figures that the disclosed arrangement of first and second backplane 102 and 108 as well as first and second computing nodes 106 and 112 may provide a substantially clear interior space 120 that can facilitate relatively unobstructed and effective air flow, potentially enhancing cooling of the components of computer chassis 100.

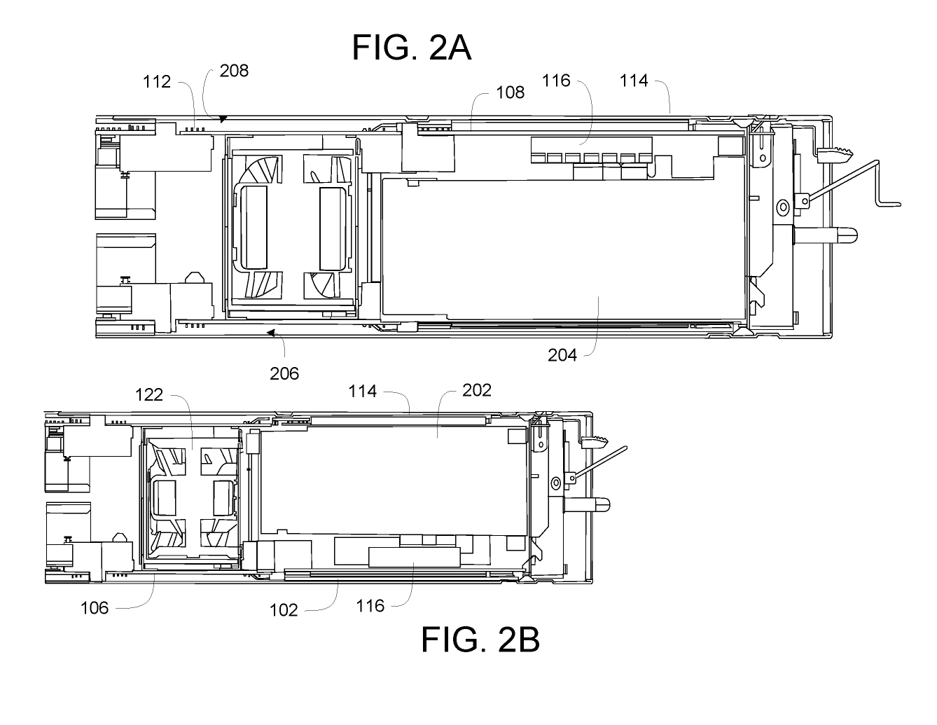

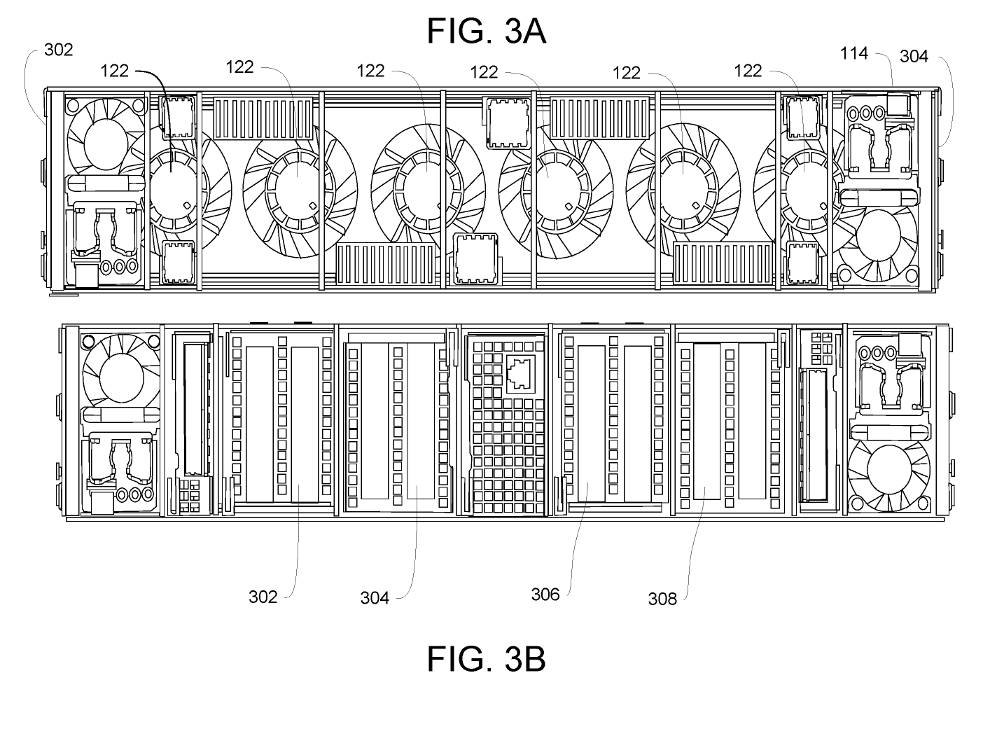

Chassis 114 can be seen in FIGS. 2A, 2B, 3A, and 3B. Chassis 114 may essentially be a box that contains the various components of computer 100, including first and second backplanes 102 and 108, associated first and second computing nodes 106 and 112, devices 202 and 204, fan(s) 122, plus other associated components such as power supply units, on-board support I/O ports, etc. A first interior surface 206 may be provided for mounting first backplane 102. Likewise, a second interior surface 208, opposing first interior surface 206, may be provided for mounting second backplane 108. It may be observed from FIG. 2A that first interior surface 206 may be substantially parallel to first surface 104, and second interior surface 208 may be substantially parallel to second surface 110. Chassis 114 may be constructed from metal, plastic, wood, composites, or any other suitable material for manufacturing a computer enclosure now known or later developed.

Fan 122 may be of a type commonly employed for computer cooling purposes, such as a brushless DC motor-driven fan, and may offer fixed or variable speeds. Multiple fans 122 may be deployed to span across the width of interior space 120. An example of such an arrangement can be seen in FIG. 3A, where a plurality of fans 122 span across interior space 120 within chassis 114, from a first side 302 to a second side 304. As can also be seen in FIG. 3A, fan 122 may be sized to a height that spans from first surface 104 to second surface 110.

Peripheral connectors 116 may be any connector suitable to allowing attachment of a peripheral device that is useable with one of the computing nodes 106 or 112. Examples of such devices include expansion cards, I/O cards, graphics processing cards, or any other card useful for the purposes for which computer 100 is employed. Each peripheral connector 116 may be an industry-standard connector, such as a Peripheral Component Interconnect Express (PCIe) connector, or another proprietary or standards-based connector.

Peripheral connectors 116 may support inserted devices in a substantially perpendicular direction extending from first surface 104 and second surface 110, which results in inserted devices extending from either the first or second surface 104, 110 to the second or first surface 110, 104, respectively. An example of this arrangement is seen in FIGS. 2A and 2B. FIG. 2B shows a first device 202 that is secured into a peripheral connector 116, and extends into interior space 120 perpendicularly from first backplane 102, extending almost to second backplane 108. Likewise, FIG. 2A shows a second device 204 secured into a peripheral connector 116 that is attached to second backplane 108. Second device 204 thus extends down through interior space 120 towards first backplane 102. Both first and second devices 202 and 204 may be arranged so that a plane defined by each device 202 and 204 extends along an axis directed toward fan 122, enhancing air flow across each device 202 and 204. This arrangement is also illustrated in FIGS. 3A and 3B.

Peripheral connectors 116 may interleave between each other. An example of this arrangement is visible in FIG. 3B. Device slots 302, associated with second backplane 108 and second computing node 112, are adjacent to device slots 304, which are associated with first backplane 102 and first computing node 106. Likewise, device slots 306, associated with another second computing node 112 connected to second backplane 108, are adjacent to device slots 308, associated with another first computing node 106 and connected first backplane 102. This arrangement results in interleaved pairs of devices 202 and 204. Other arrangements are possible; peripheral connectors 116 may stagger one-to-one, with each slot alternating between connecting to the first backplane 102 and second backplane 108.

First and second computing nodes 106 and 112 may be any module that may include components such as a central processing unit (processor), supporting circuitry, including northbridge and/or southbridge chipsets, and various associated components. In some embodiments, such associated components may include memory (both volatile storage such as RAM and non-volatile storage such as flash memory or ROM) and/or storage, such as one or more hard disk drives or solid state drives. The selection of associated components for a given computing node may depend upon the particular purpose for which the computing node is to be used and/or the types of components with which the computing node is equipped. Each computing node 106, 112 may be equipped with a computing node plug 120 that is configured to mate with a corresponding computing node connector 118. In some embodiments, each computing node may include substantially all components required for a functioning server computer. In other embodiments, each computing node may include only circuitry necessary to support one or more processors. In still other embodiments, each computing node may be application-specific, e.g. each node may be dedicated to a purpose, such as crypto-currency mining, graphics rendering, serving storage needs (such as in a SAN), etc.

Referring back to FIGS. 1A and 1B, it can be seen that computing node connectors 118 may be disposed upon an edge 124 of first backplane 102 and second backplane 108. Computing node connectors 118 may be of any type that allows each computing node to electrically interface with its corresponding backplane, and electrically communicate with each associated peripheral connector 116. Computing node connectors 118 may be of a known industry standard, or may be proprietary. In some embodiments, computing node connectors 118 may provide some measure of structural support for each associated computing node; in other embodiments, each computing node may slide into a support structure (not shown) contained within chassis 114 that provides necessary support. Computing node connectors 118 may provide electrical connections to each peripheral connector 116 to an associated computing node. In some embodiments, each computing node connector 118 may also carry additional electrical communications, such as power from a power supply, network signals from a either a network adapter or from an inserted network cable, storage interfaces, etc.

As depicted in FIG. 3B, each device 202 and 204 fits into a peripheral connector 116. Each peripheral connector 116, in turn, may be dedicated to a particular computing node 106 or 112, as described above. In the example in FIG. 3B, each computing node has two associated and electrically dedicated peripheral connectors 116. The overall length of electrical connections, from a peripheral connector 116 to an associated computing node 106 or 112, may be between 12 to 14 inches, or such other distance as any relevant electrical standard or specifications for the peripheral connectors employed may require. The position and connections of peripheral connectors 116 to each associated computing node may be selected to avoid needing retimers, or employing high-quality connecting materials.

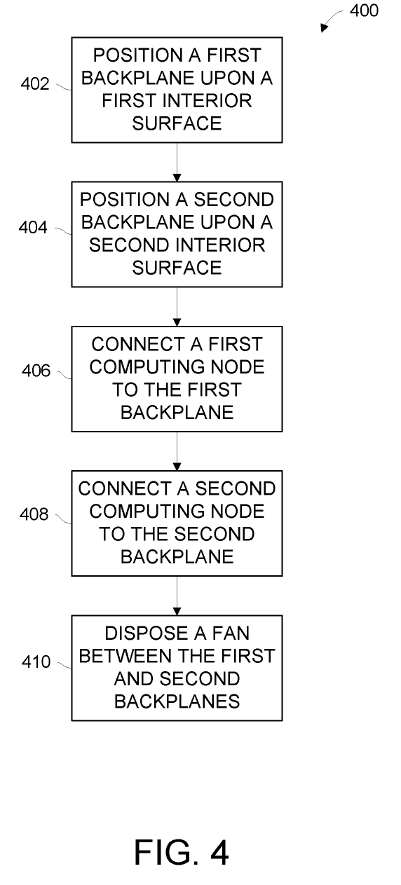

FIG. 4 depicts a method 400 for configuring computer 100. In block 402, a first backplane, such as backplane 102, may be positioned upon a first interior surface 206 (visible in FIG. 2A). A second backplane, such as backplane 108, may next be positioned upon a second interior surface 208 (also visible in FIG. 2A) in block 404. A first computing node, such as computing node 106, in block 406, may be connected to the first backplane, and in block 408, a second computing node, such as computing node 112, may be connected to the second backplane. Finally, a fan, such as fan 122, may be disposed between the first and second backplanes, such as in interior space 120, in block 410.

It will be understood that blocks 406 and 408 may be repeated if multiple computing nodes are implemented.

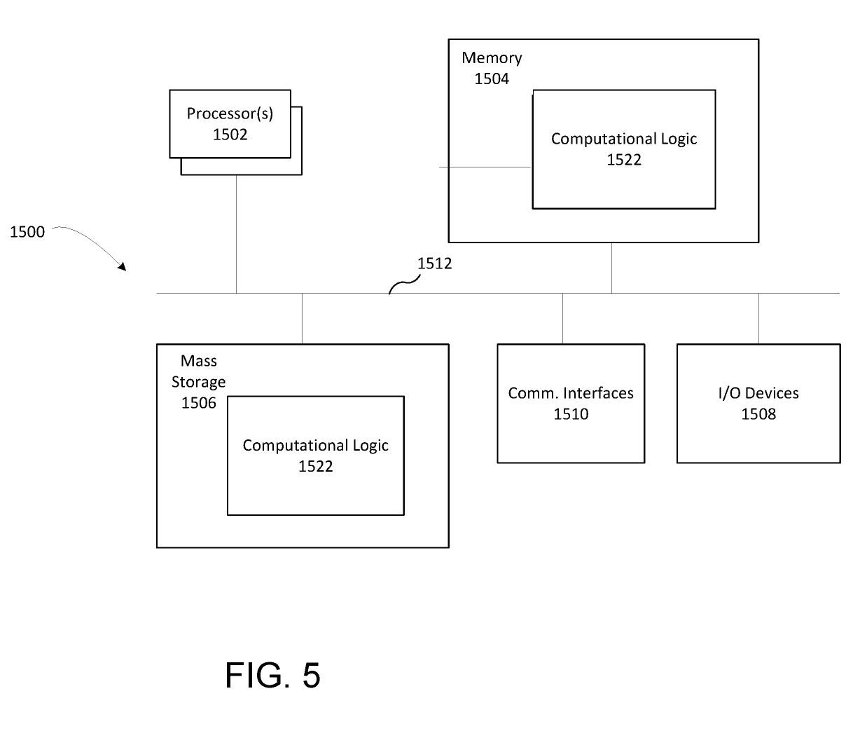

FIG. 5 illustrates an example computing device 1500 suitable for use with various components of FIG. 1, such as computing node 112 and/or a peripheral inserted into peripheral connector 116, in accordance with various embodiments. As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a central processing unit (CPU), a microprocessor, and the like. The processor 1502 may be implemented as an integrated circuit having multi-cores, e.g., a multi-core microprocessor. The computing device 1500 may include mass storage devices 1506 (such as diskette, hard drive, volatile memory (e.g., dynamic random-access memory (DRAM), compact disc read-only memory (CD-ROM), digital versatile disk (DVD), and so forth). In general, system memory 1504 and/or mass storage devices 1506 may be temporal and/or persistent storage of any type, including, but not limited to, volatile and non-volatile memory, optical, magnetic, and/or solid state mass storage, and so forth. Volatile memory may include, but is not limited to, static and/or dynamic random-access memory. Non-volatile memory may include, but is not limited to, electrically erasable programmable read-only memory, phase change memory, resistive memory, and so forth.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth). In some embodiments, the I/O devices 1508 may include various peripheral cards that are connected to peripheral connector 116, in accordance with various embodiments.

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments, such as, but not limited to, WiFi, Bluetooth, Near-Field Communications (NFC) or other wireless protocols now known or later developed.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. In particular, system memory 1504 and mass storage devices 1506 may be employed to store a working copy and a permanent copy of the programming instructions for the operation of the transmitter 102 of FIG. 1. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

In embodiments, memory 1504 may include computational logic 1522 configured as part of a computing node 112, as described in reference to FIG. 1 and elsewhere. For one embodiment, at least one of processors 1502 may be packaged together with computational logic 1522 configured to practice aspects of optical signal transmission and receipt described herein to form a System in Package (SiP) or a System on Chip (SoC).

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

### EXAMPLES

The following examples pertain to further embodiments.

Example 1 is a computer chassis apparatus comprising a first backplane with a first surface that can receive a first computing node; a second backplane with a second surface that can receive a second computing node; and a chassis that encloses the first backplane, second backplane, first computing node, and second computing node, wherein the first backplane and second backplane are substantially parallel to each other, with the first surface facing the second surface.

In Example 2, the subject matter of Example 1 can optionally include wherein the first backplane possesses a peripheral connector for accepting a peripheral card, the peripheral connector in electrical communication with the first computing node.

In Example 3, the subject matter of Example 2 can optionally include wherein the first backplane possesses a plurality of peripheral connectors; the first backplane can receive a plurality of computing nodes, the plurality of computing nodes including the first computing node; and one of the peripheral connectors is dedicated to the first computing node.

In Example 4, the subject matter of Example 2 or 3 can optionally include wherein each of the peripheral connectors is a Peripheral Component Interconnect Express (PCIe) slot.

In Example 5, the subject matter of Example 2 or 3 can optionally include wherein each of the plurality of computing nodes is directly electrically connected to at least one of the plurality of peripheral connectors.

In Example 6, the subject matter of Example 2 or 3 can optionally include wherein each of the plurality of computing nodes is electrically within 14 inches of one of the plurality of peripheral connectors.

In Example 7, the subject matter of any of Examples 1-3 can optionally include wherein the first and second backplane are spaced relative to each other to accommodate a fan disposed between the top surfaces of the first and second backplane.

In Example 8, the subject matter of Example 7 can optionally include wherein a fan is disposed between the top surfaces of the first and second backplane.

In Example 9, the subject matter of any of Examples 1-3 can optionally include wherein the first and second computing nodes each extend from the first and second backplanes, respectively, in a plane that is substantially parallel to the first and second surfaces, respectively.

Example 10 is a computer chassis, comprising a first interior surface that accepts a first backplane, the first backplane having a first surface that faces an interior space of the computer chassis; and a second interior surface parallel with and opposite the first interior surface, that accepts a second backplane, the second backplane having a second surface that faces the interior space of the computer chassis and is substantially parallel to the first surface, wherein each backplane receives a computing node.

In Example 11, the subject matter of Example 10 can optionally include wherein the first surface of the first backplane includes a peripheral connector.

In Example 12, the subject matter of Example 11 can optionally include wherein the peripheral connector is a PCIe slot.

In Example 13, the subject matter of Example 11 or 12 can optionally include wherein the peripheral connector is electrically within 14 inches from a computing node.

In Example 14, the subject matter of Example 11 or 12 can optionally include wherein the peripheral connector is in direct electrical communication with a computing node.

In Example 15, the subject matter of Example 11 or 12 can optionally include wherein the second surface of the second backplane includes a peripheral connector; and the peripheral connector of the first backplane and the peripheral connector of the second backplane are arranged so that a peripheral card inserted into the peripheral connector of the first backplane interleaves with a peripheral card inserted into the peripheral connector of the second backplane.

In Example 16, the subject matter of any of Examples 10-12 can optionally include wherein the first surface includes a first plurality of peripheral connectors and one of the first plurality of peripheral connectors is dedicated to a computing node attached to the first backplane.

In Example 17, the subject matter of any of Examples 10-12 can optionally include wherein a cooling fan is disposed in the interior space of the computer chassis between the first and second surfaces.

In Example 18, the subject matter of Example 17 can optionally include wherein the cooling fan is disposed in the interior space between the first and second backplanes, and a computing node attached to each of the first and second backplanes.

In Example 19, the subject matter of Example 17 can optionally include wherein the cooling fan is disposed to move air through the interior space of the computer chassis, between the first and second backplanes and computing nodes attached to each backplane.

In Example 20, the subject matter of any of Examples 10-12 can optionally include wherein a computing node attaches to the first backplane such that a plane defined by the computing node is in substantially the same plane as a plane defined by the first backplane.

Example 21 is a method for configuring a computer chassis, comprising positioning a first backplane with a first surface upon a first interior surface of a chassis, the first surface of the first backplane facing an interior space of the chassis; positioning a second backplane with a second surface upon a second interior surface of the chassis, the second interior surface being substantially parallel to the first interior surface, the second surface of the second backplane facing the interior space of the chassis and opposing the first surface of the first backplane; connecting a first computing node to the first backplane; and connecting a second computing node to the second backplane.

In Example 22, the subject matter of Example 21 can optionally include wherein the first surface of the first backplane includes a first plurality of peripheral connectors.

In Example 23, the subject matter of Example 22 can optionally include wherein the second surface of the second backplane includes a second plurality of peripheral connectors.

In Example 24, the subject matter of Example 23 can optionally include wherein peripheral cards plugged into the first plurality of peripheral connectors interleave with peripheral cards plugged into the second plurality of peripheral connectors.

In Example 25, the subject matter of any of Examples 22-24 can optionally include wherein one of the peripheral connectors is a PCIe slot.

In Example 26, the subject matter of any of Examples 22-24 can optionally include wherein each of the first plurality of peripheral connectors is electrically connected within 14 inches of the first computing node.

In Example 27, the subject matter of any of Examples 22-24 can optionally include wherein each of the first plurality of peripheral connectors is directly electrically connected to the first computing node.

In Example 28, the subject matter of any of Examples 21-24 can optionally include wherein connecting the first computing node to the first backplane and the second computing node to the second backplane causes each computing node to extend from the first and second backplanes, respectively, in a plane that is substantially parallel to the first and second surfaces, respectively.

In Example 29, the subject matter of any of Examples 21-24 can optionally include disposing a fan in the interior space between the first and second backplanes.

1. An apparatus comprising:
a first backplane with a first surface to receive a first computing node;
a second backplane with a second surface to receive a second computing node; and
a chassis that encloses the first backplane, second backplane, first computing node, and second computing node,
wherein:
the chassis has a first interior surface and a second interior surface parallel to and opposed so as to face the first interior surface,
the first backplane is disposed upon the first interior surface so that the first surface is parallel to and faced away from the first interior surface,
the second backplane is disposed upon the second interior surface so that the second surface is parallel to and faced away from the second interior surface, and
the first backplane and second backplane are substantially parallel to each other, with the first surface facing the second surface.

2. The apparatus of claim 1, wherein the first backplane possesses a peripheral connector for accepting a peripheral card, the peripheral connector in electrical communication with the first computing node.

3. The apparatus of claim 1, wherein:
the first backplane possesses a plurality of peripheral connectors;
the first backplane can receive a plurality of computing nodes, the plurality of computing nodes including the first computing node; and
one of the peripheral connectors is dedicated to the first computing node.

4. The apparatus of claim 2, wherein each of the peripheral connectors is a Peripheral Component Interconnect Express (PCIe) slot.

5. The apparatus of claim 2, wherein each of the plurality of computing nodes is directly electrically connected to at least one of the plurality of peripheral connectors.

6. The apparatus of claim 1, wherein the first and second backplane are disposed relative to each other to create a space between the top surfaces of the first and second backplane.

7. The apparatus of claim 6, wherein a fan is disposed in the space between the top surfaces of the first and second backplane.

8. The apparatus of claim 1, wherein the first and second computing nodes each extend from the first and second backplanes, respectively, in a plane that is substantially parallel to the first and second surfaces, respectively.

9. A computer chassis, comprising:
a first backplane having a first surface that faces an interior space of the computer chassis, the first backplane disposed upon the first interior surface so that the first surface is parallel to the first interior surface; and
a second backplane having a second surface that faces the interior space of the computer chassis, the second backplane disposed upon a second interior surface so that the second surface is parallel to the second interior surface and is substantially parallel to and faces the first surface,
wherein each backplane receives a computing node, and the first interior surface is parallel to and opposed to the second interior surface.

10. The computer chassis of claim 9, wherein the first surface of the first backplane includes a peripheral connector.

11. The computer chassis of claim 10, wherein the peripheral connector is a PCIe slot.

12. The computer chassis of claim 10, wherein the peripheral connector is in direct electrical communication with a computing node.

13. The computer chassis of claim 10, wherein:
the second surface of the second backplane includes a peripheral connector; and
the peripheral connector of the first backplane and the peripheral connector of the second backplane are arranged so that a peripheral card inserted into the peripheral connector of the first backplane interleaves with a peripheral card inserted into the peripheral connector of the second backplane.

14. The computer chassis of claim 9, wherein the first surface includes a first plurality of peripheral connectors and one of the first plurality of peripheral connectors is dedicated to a computing node attached to the first backplane.

15. The computer chassis of claim 9, wherein a cooling fan is disposed in the interior space of the computer chassis between the first and second surfaces.

16. The computer chassis of claim 15, wherein the cooling fan is disposed in the interior space between the first and second backplanes, and a computing node attached to each of the first and second backplanes.

17. The computer chassis of claim 16, wherein the cooling fan is disposed to move air through the interior space of the computer chassis, between the first and second backplanes and computing nodes attached to each backplane.

18. The computer chassis of claim 9, wherein the computing node attaches to the first backplane such that a plane defined by the computing node is in substantially the same plane as a plane defined by the first backplane.

19. A method comprising:
positioning a first backplane with a first surface upon a first interior surface of a chassis so that the first surface is parallel to the first interior surface, the first surface of the first backplane and the first interior surface facing an interior space of the chassis;
positioning a second backplane with a second surface upon a second interior surface of the chassis so that the second surface is parallel to the second interior surface, the second interior surface being substantially parallel to and facing the first interior surface, the second surface of the second backplane and the second interior surface facing the interior space of the chassis and opposing the first surface of the first backplane;
connecting a first computing node to the first backplane; and
connecting a second computing node to the second backplane.

20. The method of claim 19, wherein the first surface of the first backplane includes a first plurality of peripheral connectors.

21. The method of claim 20, wherein the second surface of the second backplane includes a second plurality of peripheral connectors.

22. The method of claim 21, wherein peripheral cards plugged into the first plurality of peripheral connectors interleave with peripheral cards plugged into the second plurality of peripheral connectors.

23. The method of claim 20, wherein each of the first plurality of peripheral connectors is directly electrically connected to the first computing node.

24. The method of claim 19, wherein connecting the first computing node to the first backplane and the second computing node to the second backplane causes each computing node to extend from the first and second backplanes, respectively, in a plane that is substantially parallel to the first and second surfaces, respectively.

25. The method of claim 19, further comprising disposing a fan in the interior space between the first and second backplanes.
